(19) United States
(12) Patent Application Publication
(10) Pub. No.: US 2009/0217960 A1
(43) Pub. Date: Sep. 3, 2009

(54) ELECTRICAL POWER SOURCE USING HEAT FROM FLUIDS PRODUCED FROM THE EARTH'S SUBSURFACE

(76) Inventors: Paulo S. Tubel, Spring, TX (US); Peter Sauermilch, Sugarland, TX (US); Clark Bergeron, The Woodlands, TX (US); Andy Cantrelle, The Woodlands, TX (US)

Correspondence Address: RICHARD A. FAGIN, P.O. BOX 1247, RICHMOND, TX, 77406-1247, US

(21) Appl. No.: 11/860,573

(22) Filed: Mar. 3, 2008

(51) Int. Cl. H01L 35/30

(52) U.S. Cl. 136/205

(57) ABSTRACT

A thermoelectric generator for producing electric power from heat in fluids produced from a subsurface wellbore includes a conduit for moving therethrough fluids produced from the Earth's subsurface and at least one thermoelectric module affixed to an exterior of the conduit. The at least one thermoelectric module includes a collimating heat transfer device in contact with the conduit on a first side and in contact with a first side of a thermoelectric generator thermocouple on a second side. A second side of the thermocouple is in contact with a contact surface of a heat sink. The heat sink is exposed to ambient atmosphere at the Earth's surface to conduct heat away from the thermocouple.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

1. Field of the Invention

The invention relates generally to the field of thermo-electric power generators. More specifically, the invention relates to using heat from fluids produced from the Earth's subsurface to generate electric power or heat from heated water as the water is injected into wellbores drilled into the Earth.

2. Background Art

Production monitoring and control devices are associated with wellbores drilled through subsurface Earth formations from which useful materials such as petroleum are withdrawn. Such monitoring and control devices can include flow meters, pressure gauges and data recording devices, among others. The monitoring and control devices may also include a wireless telemetry transceiver to communicate measurements made by various sensors to a remotely located production monitoring and control unit that records data from a plurality of such wellbores.

Irrespective of the type of monitoring and control devices used, and any associated recording and/or telemetry devices, all such devices use electric power for their operation. Accordingly, it is necessary to supply electric power in some form to operate the foregoing devices. In remote areas where grid-supplied electric power is not available, and where it is impractical to provide fuel powered electric generation, it is known in the art to use batteries, which may in some instances be recharged by photovoltaic cells (solar cells). There are circumstances where the use of photovoltaic cells becomes impractical, for example, in arctic regions where the amount of sunlight is limited. Thus, in such circumstances, battery replacement is required and adds substantially to the operating costs of such wells. Battery operation may also be impeded by low ambient temperatures under the same circumstances.

There continues to be a need for electrical power sources to operate well control and monitoring devices.

### SUMMARY OF THE INVENTION

A thermoelectric generator for producing electric power from heat in fluids produced from a subsurface wellbore according to one aspect of the invention includes a conduit for moving therethrough fluids produced from the Earth's subsurface and at least one thermoelectric module affixed to an exterior of the conduit. The at least one thermoelectric module includes a collimating heat transfer device in contact with the conduit on a first side and in contact with a first side of a thermoelectric generator thermocouple on a second side. A second side of the thermocouple is in contact with a contact surface of a heat sink. The heat sink is exposed to ambient atmosphere at the Earth's surface to conduct heat away from the thermocouple.

Other aspects and advantages of the invention will be apparent from the following description and the appended claims.

### BRIEF DESCRIPTION OF THE DRAWINGS

FIG. 1 shows a wellbore drilled and completed through a producing Earth formation in the subsurface, including an example generator module.

FIG. 2 shows an example thermoelectric generator.

FIG. 3 shows one example of one of the modules in the generator of FIG. 2.

FIG. 4 shows an example configuration for a heat sink that may be used with a thermoelectric generator module.

### DETAILED DESCRIPTION

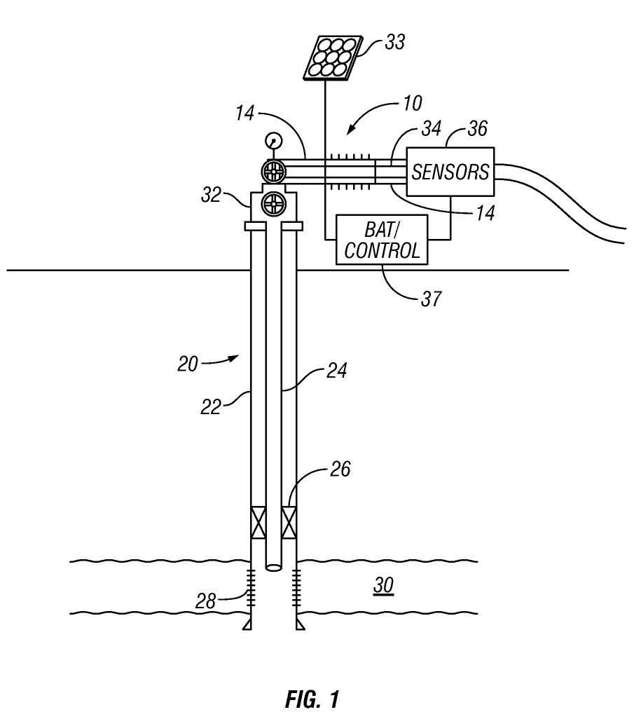

FIG. 1 shows a wellbore 20 drilled through the Earth's subsurface. The wellbore 20 may include a casing 22 cemented therein to the bottom of the wellbore 20. The casing 22 may include perforations 28 where the casing 22 passes through a productive subsurface formation 30 such as may contain oil and/or gas. A tubing string 24 may be inserted inside the casing 22 to increase the velocity of fluids produced from the productive formation 30 as they are moved by gravity to the Earth's surface. The tubing string 24 may be externally sealed near its lower end inside the casing 22 by an annular seal known as a packer 26. Control valves at the surface in a wellhead 32 are used to adjust the rate at which fluids are moved from the productive formation 30 to the Earth's surface. The tubing string 24, through one or more valves in the wellhead 32, may be connected to a surface flow line 34. The surface flow line 34 is connected at its other end to various devices (not shown) for processing the fluids that are removed from the productive formation 30.

The flow line 34 may include one or more sensors, such as temperature sensors, pressure sensors, flow meters, and the like, shown generally at 36 and coupled externally onto or coupled into the fluid flow path in the surface flow line 34. Such sensors 36 can measure selected properties of the fluids moved through the flow line 34. Output from the sensors 36 may be conducted to a control and communication unit 37. The control and communication unit 37 may include batteries (not shown separately) for providing electrical power to the sensors 36 and to operate various device (not shown separately) in the control and communication unit 37, particularly during periods of time when there is little or no fluid movement through the flow line 34. The control and communication unit 37 may include valve actuators (not shown separately) for operating one or more of the valves in the wellhead 32 or elsewhere in the wellbore system, such as in the flow line 34.

In the present example, a thermoelectric generator 10 may be affixed to the flow line 34 proximate the wellhead 32. The exterior of the flow line 34 is preferably covered with insulating material 14, for example, foamed polyurethane, to retain heat inside the flow line 34 as it passes through the thermo electric generator 10. Heat is transported from the subsurface formations because they are typically hotter that the formations proximate the surface. During periods of time when there is fluid movement through the flow line 34, the relatively high temperature of such fluids produced from the formation 30 will cause the flow line 34 to have a higher temperature than the surrounding ambient temperature at the Earth's surface. Such temperature differential may be used to generate electrical power in the thermoelectric generator 10. In some implementations a photovoltaic array 33 may be used to supplement electric power from the thermoelectric generator 10 to keep the batteries in control unit 37 at full charge.

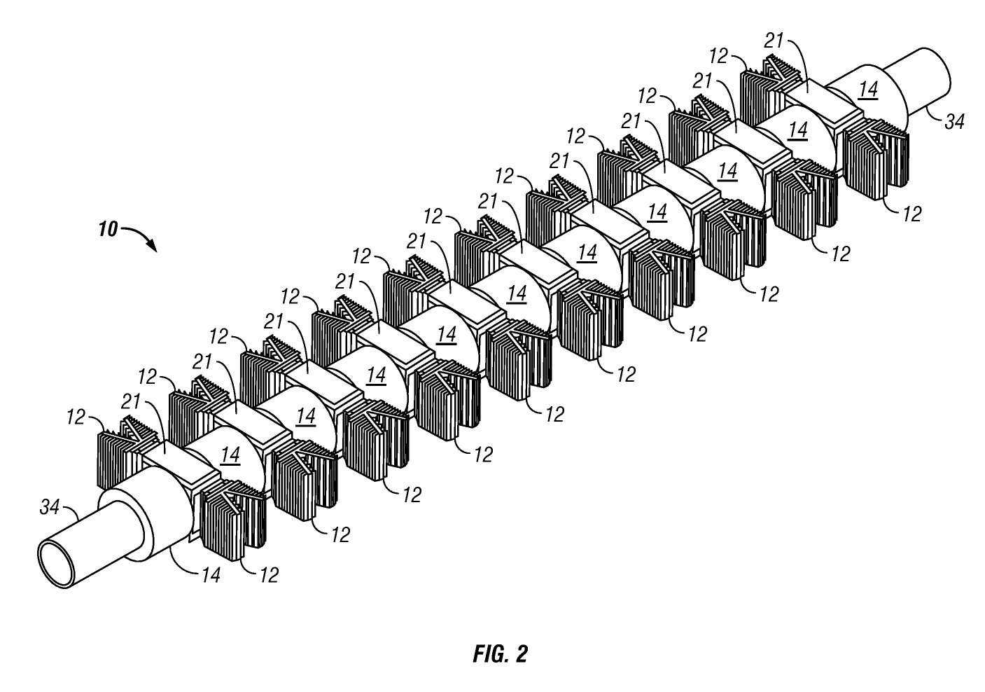

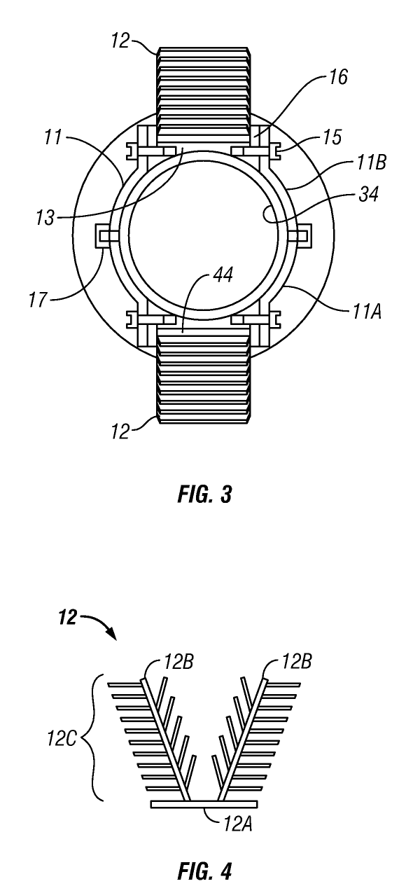

An oblique view of one example of the thermoelectric generator is shown at 10 in FIG. 2. The thermoelectric generator 10 can includes a plurality of thermoelectric generator (“TEG”) modules 21 affixed to the exterior of the flow line 34 as will be explained with reference to FIG. 3. Portions of the flow line 34 longitudinally disposed between successive TEG modules 21 may be covered with insulating material 14, or example, foamed polyurethane. Each TEG module 21 can include a heat sink 12 in contact on one side with one side of the module 21, and exposed to the ambient atmosphere on the other side, which includes heat dissipating fins or ribs (FIG. 4). The heat sink 12 may be made from aluminum or other high thermal conductivity material. In the example shown in FIG. 2, pairs of TEG modules 21 are located at a same longitudinal position along the flow line 34 so that there are active components of a TEG module disposed on opposed sides of the flow line 34. Such configuration is only meant to serve as an example and is not intended to limit the scope of the invention. Typically, the number of, and electrical connection between the TEG modules 21 will be selected to provide the voltage and current required to operate the various devices such as shown in FIG. 1.

An example of a pair of longitudinally collocated TEG modules 21 coupled to the flow line 34 is shown in FIG. 3. Each TEG module 21 includes a collimating heat transfer device 13 such as a copper, silver or other high thermal conductivity element having one face thereof shaped to conform to a selected segment of the exterior circumference of the flow line 34. The other face of the heat transfer device 13 may be substantially planar to conform to a face of a TEG thermocouple 44. Such TEG thermocouples have two substantially parallel planar faces for contact with a high temperature surface and a low temperature surface, respectively. The low temperature contact face of the TEG thermocouple 44 is in contact with the base of a corresponding heat sink 12. A clamp 11 that may be used to affix the TEG modules 21 to the flow line 34 may be assembled from two, substantially symmetric clamp components, shown at 11A and 11B in FIG. 3. Each of the clamp components may be affixed to the collimating heat transfer device 13 using cap screws 15 as shown in FIG. 3 or any other device for such coupling. Any space between the interior of the clamp component, 11A or 11B, and the collimating heat transfer device 13 may be filled with insulating material 16 to cause more of the heat inside the flow line 34 to be caused to move through the TEG thermocouple 14. As will be appreciated by those skilled in the art, the amount of power generated by a TEG thermocouple is related to the difference in temperature between the high temperature contact point and the low temperature contact point. It is preferable to operate such TEG thermocouples at relatively high differential temperatures, for example 200 degrees C. or more. However, fluids produced from the Earth's subsurface, except for very deep, very high flow rate wells, will typically not produce such temperature differentials in the flow line 34 with respect to the ambient atmosphere. It has been determined that by using a collimating heat transfer device 13 such as shown in FIG. 3, and by having the heat sink 12 include a relatively large heat dissipation area, it is possible to obtain sufficient electric power to operate devices such as explained with reference to FIG. 1 while maintaining battery charge.

The two clamp segments 11A, 1B may be coupled to each other using cap screws 17 or the like as shown in FIG. 3.

It has been determined that by increasing the available heat dissipation area of the heat sink while keeping the heat path length to such surface area minimized, it is possible to increase the efficiency of the TEG module 21. One example of a heat sink configuration that may be used in some examples of a TEG module is shown in FIG. 4. The heat sink 12 may be made from aluminum as explained earlier herein and includes a basal contact surface 12A that is configured to contact substantially all of the cold contact face of the TEG thermocouple (44 in FIG. 3). Two laterally protruding rib supports 12B may extend from the basal surface angularly displaced from each other as shown in FIG. 4. Heat dissipating ribs 12C may be affixed to the rib supports 12B as shown in FIG. 4. Thus configured, it is believed that heat moved through the heat sink may result in convection of the air in contact with the ribs 12C, thus increasing the efficiency of the TEG module 21.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A thermoelectric generator for producing electric power from heat in fluids produced from a subsurface wellbore or fluids injected into a wellbore, comprising:
a conduit for moving therethrough fluids produced from the Earth's subsurface; and
at least one thermoelectric module affixed to an exterior of the conduit, the at least one thermoelectric module including a collimating heat transfer device in contact with the conduit on a first side and in contact with a first side of a thermoelectric generator thermocouple on a second side, a second side of the thermocouple in contact with a contact surface of a heat sink, the heat sink exposed to ambient atmosphere at the Earth's surface to conduct heat away from the thermocouple.

2. The generator of claim 1 wherein the heat sink comprises ribs configured to induce convection in the ambient atmosphere.

3. The generator of claim 1 wherein the collimating heat transfer device comprises copper, the device configured to conform to the conduit on a first face and configured on a second face to conform to a high temperature face of the thermocouple.

4. The generator of claim 1 further comprising insulating material disposed between a clamp used to affix the thermocouple and lateral edges of the heat transfer device to further direct heat transfer through the heat transfer device and the thermocouple.

5. The generator of claim 1 further comprising at least a second thermoelectric generator module disposed at a same longitudinal position along the conduit at the at least one module, the at least a second thermoelectric module including a collimating heat transfer device in contact with the conduit on a first side and in contact with a first side of a thermoelectric generator thermocouple on a second side, a second side of the thermocouple in contact with a contact surface of a heat sink, the heat sink exposed to ambient atmosphere at the Earth's surface to conduct heat away from the thermocouple.

6. A thermoelectric generator system for producing electric power from heat in fluids produced from a subsurface wellbore, comprising:
a conduit for moving therethrough fluids produced from the Earth's subsurface;
at least one thermoelectric module affixed to an exterior of the conduit at each of a plurality of longitudinally spaced apart positions along the conduit, each thermoelectric module including a collimating heat transfer device in contact with the conduit on a first side and in contact with a first side of a thermoelectric generator thermocouple on a second side, a second side of the thermocouple in contact with a contact surface of a heat sink, the heat sink exposed to ambient atmosphere at the Earth's surface to conduct heat away from the thermocouple; and
an insulating sleeve affixed to the exterior of the conduit in spaces between longitudinally successive modules.

7. The system of claim 6 wherein the heat sink comprises ribs configured to induce convection in the ambient atmosphere.

8. The system of claim 6 wherein the collimating heat transfer device comprises copper, the device configured to conform to the conduit on a first face and configured on a second face to conform to a high temperature face of the thermocouple.

9. The system of claim 6 further comprising insulating material disposed between a clamp used to affix the thermocouple and lateral edges of the heat transfer device to further direct heat transfer through the heat transfer device and the thermocouple.

10. The system of claim 6 further comprising at each of the longitudinal positions at least a second thermoelectric generator module coupled to the conduit, each at least a second thermoelectric module including a collimating heat transfer device in contact with the conduit on a first side and in contact with a first side of a thermoelectric generator thermocouple on a second side, a second side of the thermocouple in contact with a contact surface of a heat sink, the heat sink exposed to ambient atmosphere at the Earth's surface to conduct heat away from the thermocouple.
